(19) United States
(12) Patent Application Publication
(10) Pub. No.: US 2008/0138694 A1
(43) Pub. Date: Jun. 12, 2008

(54) High-Temperature Fuel Cell System

(75) Inventors: Dieter Grafl, Ulm (DE); Raimund Stroebel, Ulm (DE); Markus Lemm, Blaustein (DE); Kai Lemke, Ulm (DE); Joachim Scherer, Ulm (DE); Bernd Gaugler, Ulm (DE)

Correspondence Address: MARSHALL & MELHORN, LLC, FOUR SEAGATE, 8TH FLOOR, TOLEDO, OH, 43804, US

(73) Assignee: REINZDICHTUNGS-GMBH, Neu-Ulm (DE)

(21) Appl. No.: 10/557,982

(22) PCT Filed: May 21, 2004
(86) PCT No.: PCT/EP2004/005544

§ 371 Date: Jan. 25, 2008

(30) Foreign Application Priority Data
May 22, 2003 (DE) 103 24 157.4

(51) Int. Cl. H01M 8/02; B29C 39/00; C23C 16/44; C23C 26/00; C25D 5/00

(52) U.S. Cl. 429/35; 427/58; 205/80; 264/299; 29/623.1

(57) ABSTRACT

The present invention relates to a high-temperature fuel cell system, consisting of a fuel cell stack (1) with a layering of several ceramic fuel cells (2) which in each case are separated from one another by way of interconnect layer (3). The interconnect layers comprise openings for cooling (4) or for the supply (5a) and removal (5b) of media to and from the fuel cells. The fuel cell stack may be set under mechanical compressive stress in the direction (6) of the layering. Elastic bead arrangements (7; 7′) for sealing the openings (4, 5a, 5b) or the electrically active region (10) are provided at least in regions.

The present invention relates to a high-temperature fuel cell system according to the preamble of claim 1.

High-temperature fuel cell systems are known with which a fuel cell stack is constructed with a coating of several ceramic fuel cells which in each case are separated from one another by interconnect layers. The interconnect layers at the same time have several tasks:
to electrically contact the electrode of the fuel cells and to lead the current further to the adjacent cell (series connection of the cells),
to supply the cells with reaction gases and e.g. to transport away the produced reaction waste gases via a suitable channel structure, or an inserted gas distribution structure,
to transport the waste heat arising with the reaction in the fuel cell, as well as
to mutually seal the various gas channels and to seal them to the outside.

In contrast to conventional low-temperature fuel cells (such as poly-electrolyte membrane fuel cells), high-temperature fuel cell systems has very specific peculiarities. As the name already reveals, these are operated at high-temperatures, preferably more than 500° C. and up to 1000° C. and more. Specific peculiarities arise due to this. In particular, on account of the high-temperatures only very few materials are suitable for carrying out the sealing function. For sealing the media in a secure manner over the long term, the sealing requires a lasting elasticity and must be capable of following the thermally induced relative movements of the stack components amongst one another. At temperatures of more than 500° C. this may be realised with only a few materials (e.g. high-temperature steels or ceramic materials based on mica or other layer silicates). At the same time it is also significant that an exit of these (often combustible) gases needs to be give great attention given the application of high-temperature fuel cells in the vicinity of residential houses. The individual ceramic fuel cells of the high-temperature fuel cell (also called SOFC) are connected to the interconnect layers. The interconnect layers by way of channels or applied gas distributions layers create the supply and removal of gases as well as the electrical contacting of the fuel cell. Furthermore screw connections are present which hold the stack together. These passages need to be mutually sealed, as indeed the electrically active space of the fuel cell needs to be sealed. It is indeed the actual active fuel cell composed of the anode, cathode and the central electrolyte which is located in this closed space. The electrolyte and the electrodes (anode and cathode) as a rule are ceramic and/or metal-ceramic (so-called cermet) materials and on account of this are not elastic, and are brittle. The interconnect layers are to create an optimal contact and pressing between the fuel cell and the contact layers which border these. At the same time the seals are mostly constructed to be located in the main line of force. By way of this, one hopes to compensate the tolerances of the ceramic cells.

For the supply and removal of media to and from the interconnect layers to the actual ceramic fuel cells, the interconnect layers comprise openings for the supply and removal of media.

Here difficulties often occur in particular with regard to the stability of the ceramic fuel cells and the sealing. Until now, it has been usual to carry out the sealing between the interconnect layers or between interconnect layers and the ceramic fuel cells e.g. by way of depositing ceramic glass solder onto the sealing surfaces. This glass solder may for example be composed of aluminium oxide, boron oxide, calcium oxide, barium oxide as well as silicon oxide.

However at the same time it is a problem that the sealing effect of the glass solder is achieved by way of adhering (bonding) the stack components amongst one another. For this, on heating up the fuel cell stack for the first time, the glass solder deposited on the interconnect layer is melted. The stack is compressed by way of applying mechanical compressive stress from the outside, by which means the glass solder adapts to the structure and the nature of the interconnect layers and the fuel cell and finally the individual layers of the fuel cell stack adhere (bond). By way of subsequent crystallization of the glass solder, the individual layers are firmly connected to one another and are adhered (bonded) into an almost inseparable unit. By way of this the compensation of the relative movements between the interconnect layers and the fuel cells which occur at temperature changes in the fuel cell system are greatly hindered, by which means great mechanical stress is induced in the components of the stack and their stability and life duration is significantly reduced. Furthermore, on account of the almost unreleasable bond of the individual components in the stack, the disassembly and thus its maintenance or repair is rendered much more difficult, or even impossible.

It may thus be ascertained that the greatest disadvantage of the known glass solder seals is the merely inadequate capability of compensating movements of the sealed components, and a reduced temperature change durability is created which in the long term may lead to breakage due to brittleness, and thus to dangerous leakages.

The later published DE 101 58 772 C1 shows a low-temperature fuel cell system which is suitable for PEMFC (fuel cells with a polymer electrolyte membrane). This comprises a fuel cell stack with a coating of several PEMFCs which in each case are separated from one another by interconnect layers, wherein the interconnect layers comprise openings for distributing media or for the heat exchange, and the fuel cell stack may be set under a mechanical compressive stress in the direction of the layering. Elastic bead arrangements are provided in regions for sealing openings. The fuel cell shown here is unsuitable for high-temperature applications.

It is therefore the object of the present invention to achieve a secure sealing of the openings in a fuel cell stack with as low as possible costs. The ceramic fuel cells at the same time are to be uniformly pressed with the layers bordering thereon and are to be permanently sealed with respect to the individual gas spaces, in order to effectively prevent a mixing of the gaseous media. At the same time in particular the temperature fluctuations which occur should not compromise the functioning of the sealing, and in the most favourable case the sealing system should even be able to compensate manufacturing tolerances.

This object is achieved by a high-temperature fuel cell system according to claim 1.

By way of the fact that with a fuel cell system of the known type, in particular for operating temperatures of the interconnect layers in their electrically active region averaged >300° C., preferably >500° C., at least in regions permanently elastic bead arrangements for sealing the openings and/or an electrically active region of the fuel cell system are provided, a secure sealing over a wide range of elastic compressibility (over a long elastic path) of the bead arrangement is achieved even with temperature fluctuations. With this, “openings” in the present application are to be understood as practically any regions which are to be sealed. These are preferably passage openings for a reaction gas or reaction waste gas.

The elastic bead arrangement constantly allows manufacturing tolerances of e.g. the ceramic fuel cell itself or contact materials (e.g. a metal mash) which border this to be compensated over a large tolerance range, and despite this provides an optimal sealing effect. By way of the various bead arrangements it becomes possible to adapt the compression characteristics of the bead to that of the active layer (thus of the fuel cell itself). The roughness of the materials which are in contact with the bead is preferably compensated by a suitable coating on the beads. The coating of the beads at the same time is designed such that a lasting sealing effect is ensured also at higher temperatures despite different mechanical relative movements of the fuel cell components. A compensation of these mechanical relative movements due to the massive temperature changes in operation of a high-temperature fuel cell is of decisive significance for its long-term stability.

With the bead arrangement according to the invention, the electrically active region of the fuel cells is also optimally sealed. In this the actual fuel cells are located regularly in the form of thin ceramic plates (200 μm to 0.5 mm) which are very brittle. At the same time as the case may be, it is to be taken care that in the sealing region where the electrically active region of the fuel cells meets the interconnect layers, an electrical insulation is effected, where appropriate by way of suitable coatings, in order to prevent a short circuit of the fuel cell.

Advantageous embodiments of the invention are described in the dependent claims.

One very advantageous embodiment of the invention envisages designing the bead arrangement with a thin coating having a thickness of 1 μm to 200 μm for the micro-sealing. The coating is advantageously of a temperature-resistant composite material, e.g. based on ceramic. These ceramics are composed e.g. of oxides, silicates, nitrides, carbides e.g. of the elements aluminium, silicon, boron, calcium, magnesium which for the application of the coating are processed into a suitable suspension or paste with additives such as e.g. solvents, setting agents, plastification and binding agents. Such metals as well as metal alloys may also be used as coating material which may be plastically soft deformable at the operating temperature of the high-temperature fuel cell, e.g. gold, silver. With this, the coating is advantageously effected with the screen printing method, pad printing method, stencil printing method, by way of roller deposition, by way of powder coating, with CIPC (cured in place gasket; i.e. material deposited in a liquid or pasty manner which whilst retaining the contour and shape consolidates the bead at the deposition location) or also by way of the PVD/CVD method (physical/chemical vapour deposition, i.e. precipitation from the gas phase) or galvanically. By way of these measures one succeeds in compensating the surface roughness of the components to be sealed and thus e.g. the gas diffusion through the seal is reduced to an extremely low measure.

A further advantageous embodiment form of the invention envisages providing contact-improving means, such as meshes, expanded sheet metals and/or felts of e.g. nickel or high-temperature steels between the very thin ceramic fuel cells and the interconnect layers. By way of this, on the one hand one achieves a slightly elastic compensation which additionally protects the brittle fuel cells as well as in particular an increase in the efficiency on account of improved electrical conductivity.

A further advantageous embodiment of the invention envisages the bead arrangement to contain a full bead or a half bead. At the same time within a bead arrangement it is also possible to provide both forms since depending on the course of the bead arrangement in the plane, other elasticities may prove to be useful, e.g. with tight radii a different bead geometry is more preferable than with straight courses of the bead arrangement.

A further advantageous embodiment envisages the bead arrangement to be of steel. Steel has the advantage that its forming (machining) is possible in a very inexpensive manner with common tools, furthermore e.g. methods for coating steel with thin material layers have been tried and tested. The favourable elasticity properties of steel permit the wide range of elastic compressibility to be designed well according to the invention. At the same time it particularly lends itself to attach the bead arrangement on the interconnect layer. At the same time on the one hand there exists the possibility of designing the interconnect layer as a whole as a steel shape part (which for improving the electrical contacting amongst others is provided with so-called cermet as a contact layer on the cathode of the fuel cell). It is however also possible for the interconnect layer to be designed as a composite element of two steel plates and a third steel plate lying between these. In any case the good manufacturing possibilities of steel may be exploited. It is possible to carry out the bead arrangement within a manufacturing step which takes place in any case (e.g. during embossing a flow field). By way of this very low costs occur and no additional sealing surfaces result on account of extra components, such as an additionally inserted sealing frame.

The material selection depends of course on the temperature range of the high-temperature fuel cell. The metallic materials which are outlined here are mostly steel alloys which offer an adequate strength and material compatibility with the active components of the fuel cell at the operating point of the fuel cell (e.g. based on ferrite steel alloys or nickel alloys).

Thus it is possible to adapt the compression characteristics of the bead, e.g. to a ceramic fuel cell or to a ceramic fuel cell with a contact layer lying thereon (such as a nickel mesh, etc). This however does not need to apply to ceramic fuel cells only. The characteristic line may generally be well adapted to components of a lesser elasticity. The beaded sealing may be designed in a flexible manner and thus may be used well for all fuel cell manufacturers without significant retrofitting expenses.

A further advantageous embodiment envisages the bead arrangement to comprise a stopper which limits the compression of the active layers to a minimum thickness. Here it is the case of an incompressible part of a bead arrangement or a part whose elasticity is very much lower that that of the actual bead. By way of this it is achieved that the degree of the deformation in the region is limited so that a complete pressing of the bead such that it becomes plane is ruled out.

A further advantageous embodiment envisages incorporating a largely incompressible material stable at high-temperature (e.g. based on silicates or other oxide-ceramic compounds) into the embossing which represents the sealing bead. This material similarly to the already described stopper prevents the complete plane-pressing of the bead and thus helps to improve the stability and the function of the seal and the ceramic fuel cell.

A further advantageous embodiment envisages arranging the bead arrangement on a component which is separate from the interconnect layer. This is particularly favourable if the interconnect layers consist of material such as ceramics which is not suitable for bead arrangements. The separate component is then applied onto the interconnect layer or is integrated in a e.g. ceramic interconnect layer so that as a whole a sealing connection arises between the separate components and the interconnect layer.

Finally a further advantageous embodiment envisages designing the bead arrangement of a beading of an inorganic material, i.e. mica or mineral fibre. Such a bead may be deposited with the screen printing method or the stencil printing method. It serves for the micro-sealing as well as for the macro-sealing. The beading also assumes the function of adapting the compression of the individual components.

It may thus be ascertained that the bead arrangement according to the invention may have various embodiments. For reasons of manufacture, in a practical manner it may be a direct component of the interconnect layer. It may however also exist as an extra structure which is preferably connected to the interconnect layer.

The beads of the system according to the invention preferably comprise openings for leading through liquid and/or gaseous media. These are described in the German Patent application DE 102 48 531 (date of filing 14.10.2002). All bead variations described here, including their openings and inner structures of the bipolar plate/interconnect layer are incorporated into this application by way of reference.

Further advantageous further developments of the present invention are specified in the remaining dependent claims.

The present invention is now explained by way of several figures. There are shown in:

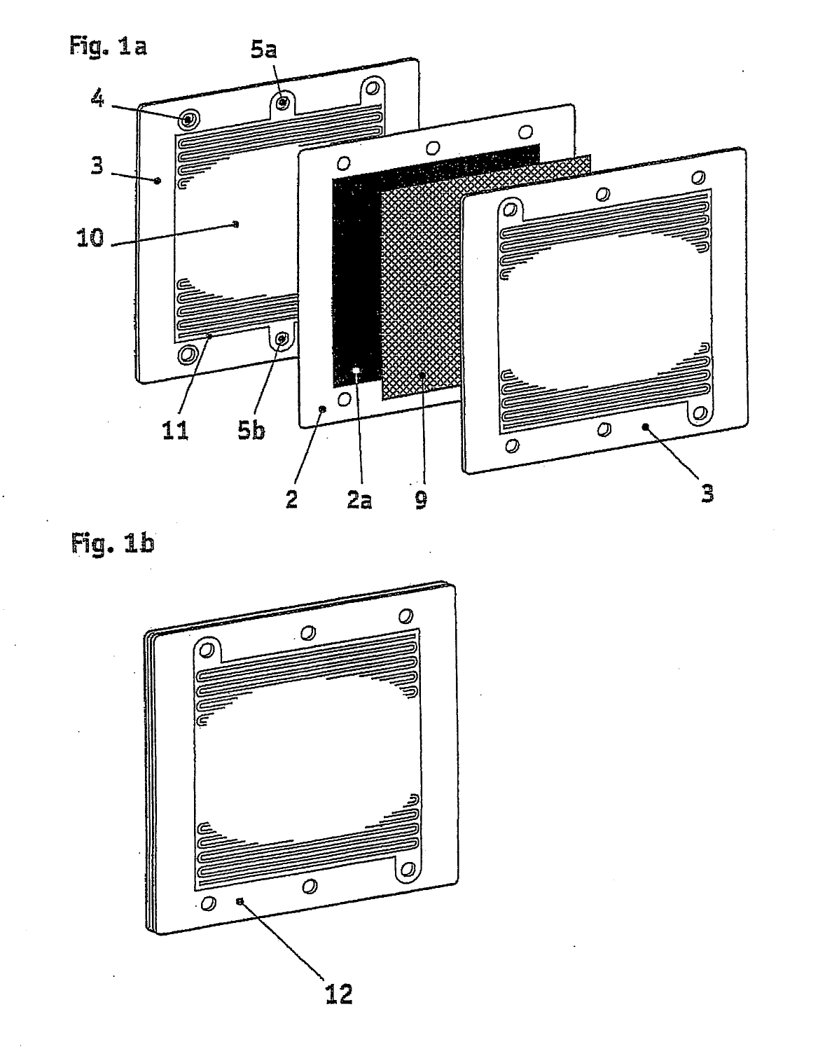

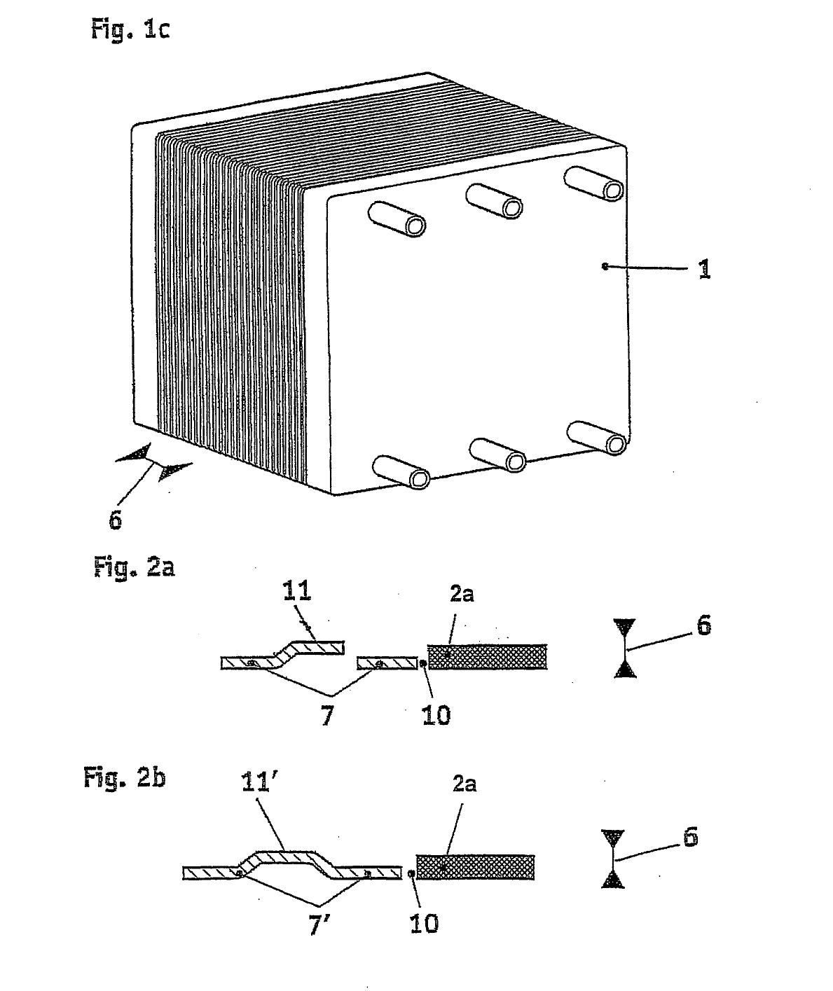

FIGS. 1a to 1c the manner of construction of the fuel cell stack,

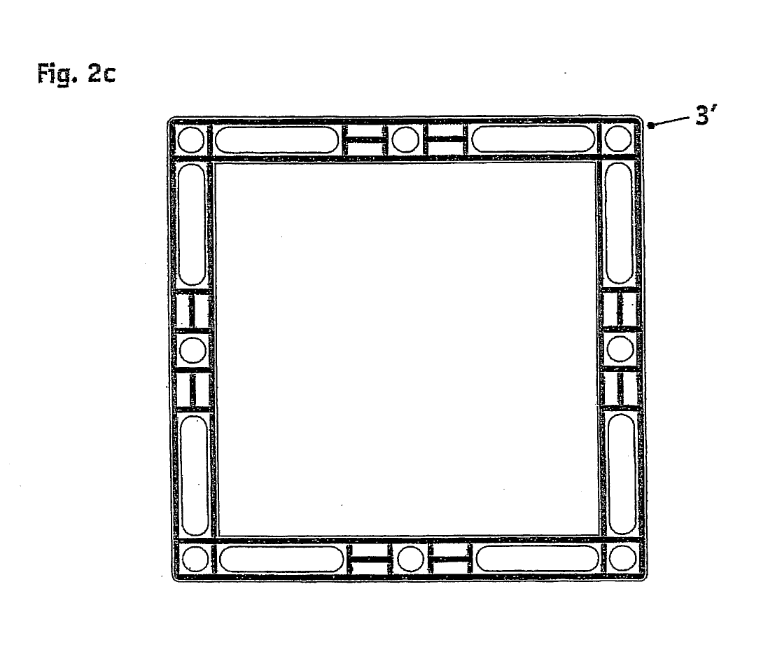

FIGS. 2a and 2b embodiments of bead arrangements according to the invention,

FIG. 2c a plan view of a interconnect layer according to the invention,

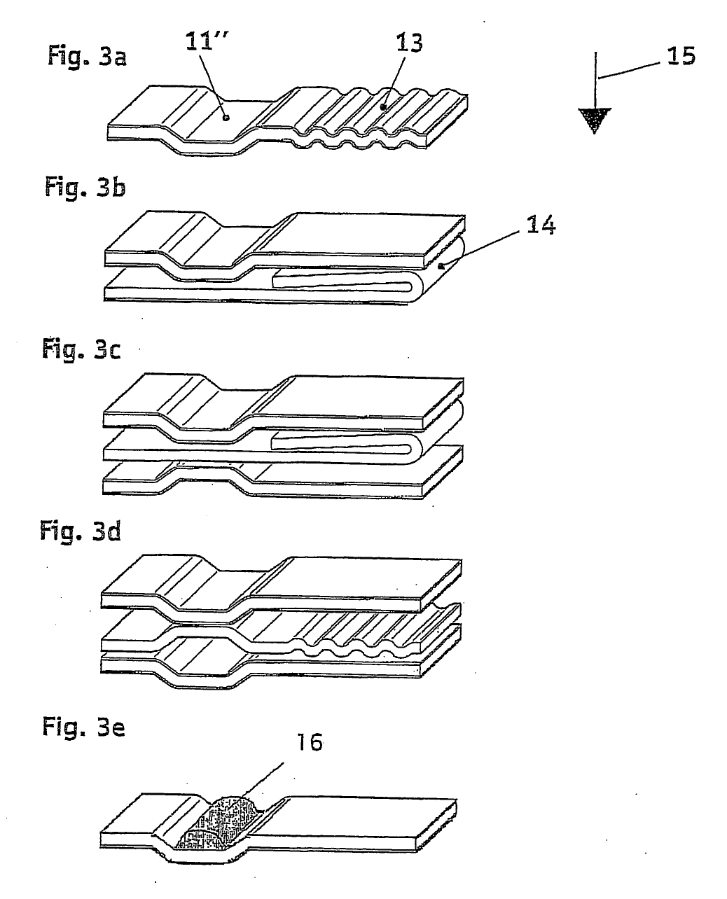

FIGS. 3a to 3e several bead arrangements with a stopper.

FIG. 1a shows the construction of a high-temperature fuel cell arrangement 12, as is shown in FIG. 1b. A multitude of fuel cell arrangements 12 in a layered manner forms the region of a fuel cell stack 1 arranged between the end plates (see FIG. 1c).

In FIG. 1a one can see a ceramic fuel cell 2 with its regular components, which comprises an ion-conductive, ceramic electrolyte which is electrically active in the middle region (a region which is arranged around this may optionally be is designed in an electrically insulated manner). Two interconnect layers 3 are arranged in the fuel cell arrangement 12 between which the fuel cell 2 is arranged. In the region between each interconnect layer and the fuel cell there is arranged a nickel mesh 9 for improving the electrical contact and this is dimensioned such that it may be accommodated in a recess of the interconnect layer. This nickel mesh is however not absolutely necessary for the functioning of the fuel cell system, it is only to be regarded as optional. In the assembled condition of the fuel cell arrangement 12, the electrically active region of the fuel cells which here are covered by the nickel mesh 9 is arranged in an essentially closed space 10 (this corresponds essentially to the above mentioned recess of the interconnect layer) which is limited laterally by a bead 11 in an essentially peripheral manner. This closed space 10 is gas-tight due to a bead 11 which belongs to the bead arrangement 7 or 7′ (see FIGS. 2a and 2b).

Gas openings for the supply of media 5a as well as for the removal of media 5b lie within the sealing region and by way of the bead 11 are sealed with respect to further gas openings, such as the passage openings e.g. for cooling 4 (which have a bead of their own for sealing). The sealing effect at the same time takes place at all beads by way of the exertion of pressure onto the fuel cell stack 1 in the direction 6 of the layering (see FIG. 1c). This e.g. is effected by way of screw connections or tension strips, which are not shown in this case. The bead 11 offers the advantage that it has a wide range of elastic compressibility in which it displays an adequate sealing effect. This is particularly advantageous for sealing the electrically active region of the fuel cell 2 (here optional, additional layers such as a nickel mesh 9 may be provided for improving the contact). An adaptation of the bead to the geometry of the ceramic fuel cell is easily possible on account of the broad elastic compression range of the bead 11. With this, one succeeds on the one hand in providing a lateral sealing, and on the other hand an adequate gas distribution in the plane of the fuel cells is provided and also the pressing pressure in the layer direction 6 is uniform and sufficiently large in order to achieve a uniform conduction of current. For improving the micro-sealing, the bead 11 on its outer side is provided with a coating of a ceramic material or also gold or silver, wherein this coating e.g. is deposited with the screen printing method or by way of powder coating.

In order to limit the pressing of the ceramic fuel cell, the bead design is designed with a stopper. With regard to this stopper which may be designed as a fold-over, as a wave-stopper (corrugated stopper) or also as a trapezoidal stopper, this is described again in more detail further below with the description of the FIGS. 3a to 3d. The stoppers all have the function of being able to limit the compression of the beads to a minimum extent.

The interconnect layer 3 is chiefly designed as a metal shape part. That which has already been discussed with regard to the easy manufacturability as well as the advantages of metals in the context of bead arrangements is referred to. Also special steel alloys are known which by way of a suitable alloy composition or by way of incorporating ceramic nanoparticles (so-called oxide dispersions) into the metal structure, may be adapted to the conditions at very high-temperatures (>600° C.). At the same time by way of the modification of the steel alloy, the strength of the metal is increased, and its coefficient of thermal expansion is adapted to the mechanical properties of the brittle ceramic fuel cell (so-called ODS=oxide dispersion stabilised alloys).

If the interconnect layer e.g. is formed of metal which is not suitable for the manufacture of suitable bead geometries with the required elasticities, the bead region may also be designed of another suitable material (e.g. alloys based on chromium and nickel). A connection of the separate bead component to the interconnect layer is effected by way of joining methods such as soldering, locking-in, welding, peripheral casting, riveting. If the interconnect layer are of a material other than metal, e.g. of suitable non-ion conducting ceramics (mostly perovskite, such as doped lanthanum chromite) the bead region may be designed as a frame of a suitable material. The base material of the interconnect layer which contains the flow field is connected in a gas-tight and fluid-tight manner by way of joining methods such as melting, peripheral injection, welding, soldering, riveting, locking-in.

FIGS. 2a and 2b show two embodiment forms of a bead arrangement according to the invention. In FIG. 2a a cross section through the bead arrangement 7 is shown which shows the bead 11 which is designed as a half bead. The essentially peripheral bead 11 as already explained in the embodiments with regard to FIG. 1a, encloses the ceramic fuel cell 2 or the electrically active region 2a of the fuel cell 2, as the case may be with contact layers lying thereon, which here however are not shown. In FIG. 2a the bead 11 is design as a so-called half bead thus e.g. in a quarter-circle shaped manner. Since the fuel cell 2 or its electrically active region 2a needs to be enclosed by the seal, and crossings in the region of the media channels occur (see FIG. 2c), an alternate design as a full bead or half bead is required. With this, a full bead may merge into two half beads which then in each case by themselves have a sealing effect. Apart from this the application of a full bead or half bead creates the possibility of adapting the elasticity within a large region. The coating for the micro-sealing is shown by way of a hatching on the surface of the bead.

FIG. 2a shows the bead arrangement 7 in the unpressed condition. On exerting a mechanical compressive stress onto the fuel cell stack, a pressing in the direction 6 is effected so that the bead arrangement 7 or the bead 11 with respect to the fuel cell 2 or the electrically active region 2a forms a gas-tight lateral sealing for the closed space 10.

FIG. 2b shows a further bead arrangement, the bead arrangement 7′. The only difference of this arrangement to that of FIG. 2a lies in the fact that here a bead 11′ is designed as a full bead (here with an approximately semicircular cross section). An optional micro-seal already described above is shown on this by way of cross hatching. There are still numerous further embodiments of the present invention. Thus e.g. it is possible to design bead geometries other than those shown here. Multiple beads are also possible. Further, the bead arrangement according to the invention is also possible to be used for all seals in the region around the actual fuel cell stack. Thus it is not only possible to seal the electrically active region around the actual fuel cell, but also any passages for the gaseous media etc. With the sealing in screw holes for tensioning the fuel cell arrangement, the elasticity of the bead arrangement may be used in order to counteract a setting procedure in the stack and to compensate possible tolerances.

FIG. 2c shows a plan view of a further embodiment 3′ of a interconnect layer according to the invention. With this the bead arrangements in the plan view may be recognised by the broad lines. The seal arrangements at the same time serve for sealing several passage openings.

FIGS. 3a to 3e show various bead arrangements which in each case have a stopper. This stopper serves for limiting the deformation of a bead such that this may not be pressed together beyond a certain measure.

Thus FIG. 3a shows a single-layered bead arrangement with a full bead 11″, whose deformation limitation in the direction 15 is achieved by way of a wave stopper 13. FIG. 3b shows a two-layer bead arrangement with which a full bead of the upper layer is limited in its deformation by way of a folded-over sheet metal plate lying below it. FIGS. 3c as well as 3d show bead arrangements with which at least two full beads are opposite one another and for limiting the deformation either a folded-over region (see FIG. 3c) or a corrugated sheet metal plate (see FIG. 3d) is provided.

FIG. 3e shows a largely incompressible bead 16 incorporated in the embossing of the bead, which likewise acts as a stopper according to the invention.

What is claimed is:

1-14. (canceled)

15. A high-temperature fuel cell system comprising:
a fuel cell stack having a plurality of fuel cells;
an interconnect layer having passage openings and an electrically active area; and
at least one bead arrangement for sealing at least one of said passage openings and said electrically active area, said interconnect layer and said at least one bead arrangement being disposed between said first fuel cell and said second fuel cell.

16. The fuel cell system of claim 15, wherein said plurality of fuel cells are formed from at least one of a ceramic and a metal-ceramic material.

17. The fuel cell system of claim 15, wherein said passage openings selectively supply and remove a reaction media or a cooling media.

18. The fuel cell system of claim 15, wherein said interconnect layer is in at least one of a mechanical communication and electrical communication with at least one of said first fuel cell and said second fuel cell.

19. The fuel cell system of claim 15, wherein said interconnect layer includes at least one of a metal mesh, an expanded sheet metal, and a metal felt disposed between said interconnect layer and at least one of said plurality of filet cells.

20. The fuel cell system of claim 15, wherein said at least one bead arrangement includes a coating for micro-sealing of a reaction media or a cooling media.

21. The fuel cell system of claim 20, wherein said coating is at least one of a ceramic coating and a metallic coating.

22. The fuel cell system of claim 21, wherein said coating includes screen printing, pad printing, stencil printing, roller deposition, powder coating, cured in place gasket process, physical vapor deposition, chemical vapor deposition, and galvanic process.

23. The fuel cell system of claim 15, wherein said at least one bead arrangement includes at least one full bead.

24. The fuel cell system of claim 15, wherein said at least one bead arrangement includes at least one half bead.

25. The filet cell system of claim 15, wherein said at least one bead arrangement is formed from at least one metallic layer.

26. The fuel cell system of claim 15, wherein said at least one bead arrangement includes at least one stopper.

27. The fuel cell system of claim 15, wherein said at least one bead arrangement is integral with said interconnect layer.

28. The filet cell system of claim 27, wherein said at least one bead arrangement is integral with said interconnect layer with no additional sealing surface on account of extra components.

29. The fuel cell system of claim 15, wherein said at least one bead arrangement is secured to said interconnect layer.

30. The filet cell system of claim 29, wherein said at least one bead arrangement is secured to said interconnect layer by at least one connection process including soldering, snapping-in, welding, soldering-in, and peripheral casting.

31. The fuel cell system of claim 15, wherein said at least one bead arrangement is disposed at least around a periphery of said electrically active area.

32. The fuel cell system of claim 15, wherein said at least one bead arrangement includes a ceramic bead.

33. The fuel cell system of claim 32, wherein said ceramic bead is located in the embossing of said at least one bead arrangement.

34. A high-temperature fuel cell system comprising:
a fuel cell stack having a plurality of high-temperature fuel cells;
an interconnect layer having passage openings and an electrically active area, said interconnect layer being disposed between a first fuel cell and a second fuel cell;
at least one bead arrangement for sealing at least one of said passage openings and said electrically active area, said at least one bead arrangement being disposed between said first fuel cell and said second fuel cell, said at least one bead arrangement being formed from at least one metallic material; and
whereby said at least one bead arrangement is in mechanical communication with said first fuel cell and said second fuel cell, said at least one bead arrangement includes at least one bead being in the form of a full bead or a half bead, said bead arrangement being disposed proximate a periphery of at least one of said passage openings and said electrically active area.

35. The fuel cell system of claim 34, wherein said at least one bead arrangement provides sealing for said passage openings.

36. The fuel cell system of claim 34, wherein said at least one bead arrangement provides sealing for said electrically active area.

37. The fuel cell system of claim 34, wherein said at least one bead arrangement includes a coating for micro-sealing of a reaction media or a cooling media.

38. A method of manufacturing a high-temperature fuel cell system comprising:
assembling a fuel cell stack having a plurality of fuel cells;
providing an interconnect layer having passage openings and an electrically active area, said interconnect layer being disposed between a first fuel cell and a second fuel cell of said plurality of fuel cells, said interconnect layer having at least one bead arrangement for sealing at least one of said passage openings and said electrically active area, said at least one bead arrangement being disposed between said first fuel cell and said second fuel cell; and
forming at least one bead in the form of a full bead or a half bead disposed proximate a periphery of at least one of said passage openings and said electrically active area.

39. The method of claim 38, further comprising placing a coating on at least a portion of said at least one bead arrangement.

40. The method of claim 39, wherein said placing said coating includes screen printing, pad printing, stencil printing, roller deposition, powder coating, cured in place gasket process, physical vapor deposition, chemical vapor deposition, and galvanic process.

41. The method of claim 38, wherein said at least one bead arrangement is integral with said interconnect layer.

42. The method of claim 41, wherein said at least one bead arrangement is integral with said interconnect layer by a manufacturing step of the interconnect layer that takes place in any case.

43. The method of claim 38, wherein said at least one bead arrangement is secured to said interconnect layer by at least one connection process including soldering, snapping-in, welding, soldering-in, and peripheral casting.
